(19) United States
(12) Patent Application Publication
(10) Pub. No.: US 2018/0287238 A1
(43) Pub. Date: Oct. 4, 2018

(54) Transmission Line and Manufacturing Method Thereof

(71) Applicant: Yazaki Corporation, Tokyo (JP)

(72) Inventors: Mizuki Shirai, Susono-shi (JP); Hiroki Kondo, Susono-shi (JP)

(73) Assignee: Yazaki Corporation, Tokyo (JP)

(21) Appl. No.: 15/942,787

(22) Filed: Apr. 2, 2018

(30) Foreign Application Priority Data
Apr. 3, 2017 (JP) 2017-073446

(51) Int. Cl. H01P 3/08; H01P 11/00; H05K 1/02; H05K 3/00

(52) U.S. Cl. CPC H01P 3/08; H01P 11/003; H05K 2201/09036; H05K 3/0014; H05K 2201/093; H05K 1/0216

(57) ABSTRACT

A transmission line includes a plurality of conductor patterns as transmission paths of signals arranged in parallel in a planar shape, an insulating layer surrounding the plurality of conductor patterns in a substantially planar shape, a first ground pattern formed on one surface side of the insulating layer, and a second ground pattern formed on the other surface side of the insulating layer. The insulating layer includes one or more grooves formed continuously in a longitudinal direction of the plurality of conductor patterns on the one surface side without dividing the insulating layer at each of one or more positions between the plurality of conductor patterns in a plan view. The first ground pattern is continuously formed over the one surface side.

### CROSS REFERENCE TO RELATED APPLICATIONS

This application claims priority from Japanese Patent Application No. 2017-073446 filed on Apr. 3, 2017, the entire contents of which are incorporated herein by reference.

### BACKGROUND OF THE INVENTION

### Field of the Invention

The present invention relates to a transmission line and a manufacturing method thereof.

### Description of Related Art

In the related art, a transmission line formed by surrounding a conductor pattern with an insulating layer has been suggested. In such a transmission line, a plurality of conductor patterns are provided in parallel in some cases, and for example, in a case where the plurality of conductor patterns are used as signal lines, crosstalk between signal lines becomes a problem. In order to deal with such a problem, there have been suggested a technology in which holes that extend in the longitudinal direction of the pattern are formed at positions between the conductor patterns, or a technology in which the conductor pattern is offset in the vertical direction (for instance, see Patent Literature 1: JP-A-2016-92561). In addition, in order to reduce the crosstalk, it is also effective to increase the distance between the conductor patterns.

### [Patent Literature 1] JP-A-2016-92561

According to a related art, crosstalk cannot be reduced only by providing holes between conductor patterns similar to transmission line. In order to reduce crosstalk, in a case where the conductor pattern is offset in a vertical direction similar to the transmission line, a structure becomes complicated. In addition, in a case where the distance between the conductor patterns increases, since it is necessary to provide a sufficiently large distance, the transmission line becomes large.

One or more embodiments provide a transmission line which is capable of preventing complication and an increase in size of a structure when reducing crosstalk, and a manufacturing method of a transmission line which can prevent complication of a manufacturing process.

In an aspect (1), one or more embodiments provide a transmission line including a plurality of conductor patterns as transmission paths of signals arranged in parallel in a planar shape, an insulating layer surrounding the plurality of conductor patterns in a substantially planar shape, a first ground pattern formed on one surface side of the insulating layer, and a second ground pattern formed on the other surface side of the insulating layer. The insulating layer includes one or more grooves formed continuously in a longitudinal direction of the plurality of conductor patterns on the one surface side without dividing the insulating layer at each of one or more positions between the plurality of conductor patterns in a plan view. The first ground pattern is continuously formed over the one surface side.

According to the aspect (1), since the insulating layer has grooves at each of the positions between the plurality of conductor patterns, and the first ground pattern is continuously formed over the one surface side, the ground pattern is disposed so as to enter between the plurality of conductor patterns, and accordingly functions as a shield foil, thereby reducing crosstalk. Therefore, it is not necessary to sufficiently ensure the distance between the conductor patterns and it is possible to prevent the increase in size. In addition, since the conductor patterns are arranged in parallel in a shape of a plane, it is also not necessary to form the conductor patterns by offsetting the patterns. As a result, the complication of the structure can be prevented. Therefore, it is possible to provide a transmission line which is capable of preventing complication and an increase in size of the structure when reducing crosstalk. In addition, since the groove does not divide the insulating layer, the transmission line is not connected in the width direction only by the ground pattern, and is advantageous in terms of strength.

In an aspect (2), each of the one or more grooves has a depth which is equal to or greater than a depth of the plurality of conductor patterns from a top surface of the one surface side.

According to the aspect (2), since each of the one or more groove is formed to have a depth which is equal to or greater than the arrangement depth of the plurality of conductor patterns, the ground pattern enters between the plurality of conductor patterns, and accordingly, the effect as a shield foil is further enhanced. Therefore, crosstalk can be further reduced.

In an aspect (3), each of the one or more grooves has a V shape in a sectional view.

According to the aspect (3), since the each of the one or more grooves is formed to have a V shape in a sectional view, it is possible to stabilize the crosstalk reduction effect.

In an aspect (4), a manufacturing method of a transmission line includes extrusion-molding an insulating resin into a plurality of conductor patterns as transmission paths of signals arranged in parallel in a planar shape, so as to form an insulating layer surrounding the plurality of conductor patterns in a substantially planar shape, forming a first ground pattern on one surface side of the insulating layer formed in the extrusion-molding, and forming a second ground pattern on the other surface side of the insulating layer formed in the extrusion-molding. In the extrusion-molding, the insulating resin is extrusion-molded with a mold having a projected portion, so as to continuously form one or more grooves in a longitudinal direction of the plurality of conductor patterns without dividing the insulating layer at each of one or more positions between the conductor patterns in a plan view. In the forming the first ground pattern, the first ground pattern is continuously formed over the one surface side.

According to the aspect (4), the insulating resin is extrusion-molded by a mold having a projected portion, so as to form one or more grooves of the insulating layer having the one or more grooves continuously in the longitudinal direction, in a process similar to that of the insulation layer that does not have a groove, it is possible to form an insulating layer having grooves, and to mitigate complication of the manufacturing process. Therefore, as the manufacturing method of the transmission line which can prevent complication and an increase in size of the structure when reducing crosstalk, it is possible to provide a manufacturing method in which the complication of the manufacturing process is prevented.

According to one or more embodiments, it is possible to provide a transmission line and a manufacturing method thereof which can prevent the complication of the manufacturing process and the increase in size when reducing crosstalk.

### BRIEF DESCRIPTION OF THE DRAWINGS

FIG. 1 is a perspective view illustrating a transmission line according to an embodiment of the invention;

FIG. 2 is a sectional view of the transmission line illustrated in FIG. 1;

FIG. 3 is a sectional view illustrating a first manufacturing method of the transmission line illustrated in FIGS. 1 and 2;

FIG. 4 is a sectional view illustrating a second manufacturing method of the transmission line illustrated in FIGS. 1 and 2;

FIGS. 5A and 5B are graphs illustrating characteristics of a transmission line according to a comparative example, wherein FIG. 5A illustrates impedance characteristics, and FIG. 5B illustrates crosstalk reduction characteristics;

FIGS. 6A and 6B are graphs illustrating characteristics of the transmission line according to the embodiment, wherein FIG. 6A illustrates impedance characteristics, and FIG. 6B illustrates crosstalk reduction characteristics;

FIG. 7 is a sectional view illustrating a transmission line according to a second embodiment;

FIGS. 8A and 8B are graphs illustrating characteristics when the width of a groove changes in the transmission line according to the first embodiment, wherein FIG. 8A illustrates impedance characteristics, and FIG. 8B illustrates crosstalk reduction characteristics; and

FIGS. 9A and 9B are graphs illustrating characteristics when the width of a groove changes in the transmission line according to the second embodiment, wherein FIG. 9A illustrates impedance characteristics, and FIG. 9B illustrates crosstalk reduction characteristics.

### DETAILED DESCRIPTION

Hereinafter, the invention will be described in accordance with appropriate embodiments. In addition, the invention is not limited to the embodiments which will be described hereinafter, and can be appropriately changed without departing from the spirit of the invention. In addition, in the embodiments which will be described hereinafter, there is a position at which illustration or description of a part of the configuration is omitted, but it is needless to say that appropriately known or well-known technology is employed as the omitted details of the technology within the range in which contradiction to the contents to be described hereinafter is not generated.

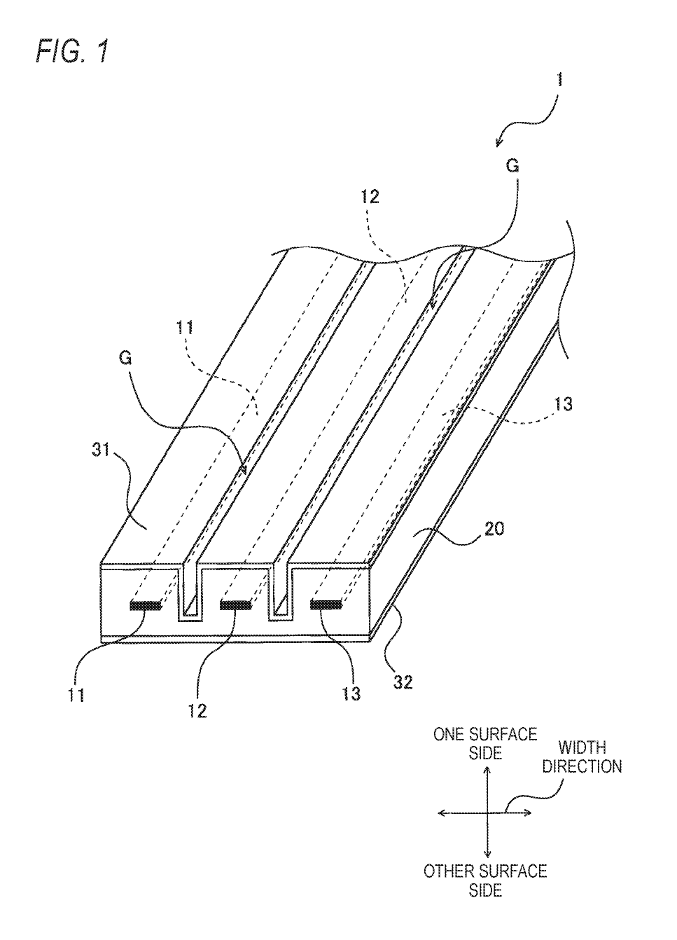

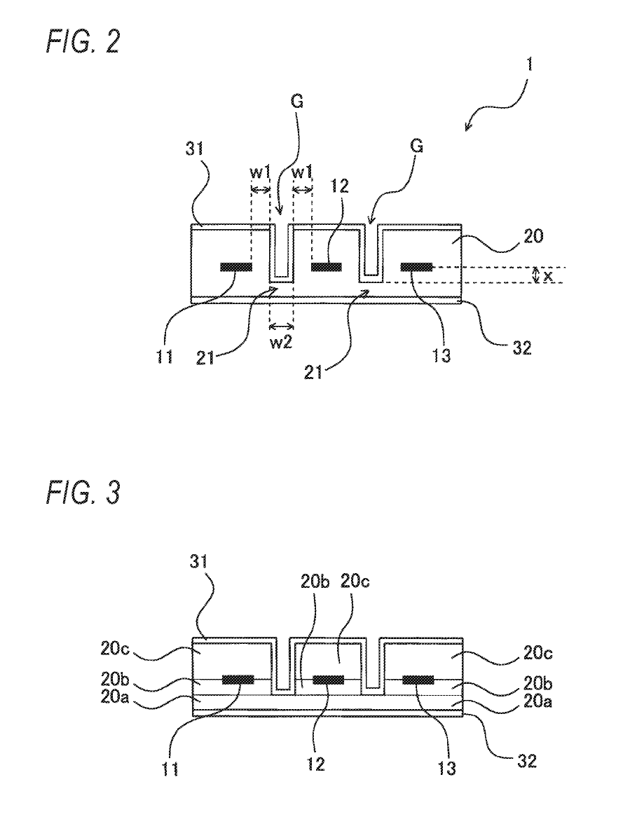

FIG. 1 is a perspective view illustrating a transmission line according to an embodiment of the invention, and FIG. 2 is a sectional view of the transmission line illustrated in FIG. 1. As illustrated in FIGS. 1 and 2, the transmission line 1 includes a plurality (for example, three) of conductor patterns 11 to 13 that serve as transmission paths of signals arranged in parallel in a planar shape; an insulating layer 20 which surrounds the plurality of conductor patterns 11 to 13 and makes a substantially planar shape; a first ground pattern 31 which is formed on one surface side of the insulating layer 20; and a second ground pattern 32 which is formed on the other surface side of the insulating layer 20.

In the embodiment, the first to third conductor patterns 11 to 13 are planar circuits for high-frequency signal transmission, and are made of, for example, a copper material. The insulating layer 20 is a dielectric made of, for example, an insulating resin. In addition, the ground patterns 31 and 32 are made of, for example, a copper material similar to the first to third conductor patterns 11 to 13. In addition, the ground patterns 31 and 32 are grounded.

Here, since the first to third conductor patterns 11 to 13 are arranged in parallel in a planar shape, the patterns are provided at the same height without being offset in the height direction. Furthermore, the insulating layer 20 has a groove G that has a recessed shape in a sectional view on one surface side. The grooves G are formed at respective positions between the plurality of conductor patterns 11 to 13 in a plan view of the transmission line 1 (when viewed from the one surface side), and are continuous along the longitudinal direction of the conductor patterns 11 to 13.

In addition, the grooves G are formed without dividing the insulating layer 20 in a sectional view. Therefore, the insulating layer 20 has a connecting portion 21 on the lower part (the other surface side) of the groove G. In other words, although the grooves G are formed, the insulating layer 20 has a structure connected in the width direction via the connecting portion 21.

Here, although the depth of the groove G is not particularly limited, it is preferable that the depth of the groove G is equal to or greater than the arrangement depth of the plurality of conductor patterns 11 to 13 (that is, the depth of the groove G is equal to or greater than the arrangement depth of the plurality of conductor patterns 11 to 13). More specifically, in the embodiment, each of the conductor patterns 11 to 13 is disposed at a position which is a middle position of the thickness of the insulating layer 20. It is preferable that the groove G is formed from one surface side, and a bottom surface thereof reaches the other surface side to the same extent as or beyond the intermediate position.

Furthermore, the first ground pattern 31 is continuously formed inside and outside the groove G so as to follow the unevenness of the groove G. Therefore, the first ground pattern 31 enters between the plurality of conductor patterns 11 to 13.

The transmission line 1 is manufactured by the following manufacturing method. Hereinafter, a manufacturing method of the transmission line 1 will be described below.

FIG. 3 is a sectional view illustrating a first manufacturing method of the transmission line 1 illustrated in FIGS. 1 and 2. The first manufacturing method is a method of laminating various materials and the like. First, as illustrated in FIG. 3, a first insulating film 20a (for example, a liquid crystal polymer sheet) is placed on a metal foil that serves as the second ground pattern 32. Next, three second insulating films 20b are laminated on the first insulating film 20a with intervals therebetween. In addition, the interval provided here corresponds to the width of the groove G (reference numeral w2 illustrated in FIG. 2).

Next, three conductor patterns 11 to 13 are placed on the three second insulating films 20b. At this time, in consideration of the width w1 of the position that serves as the groove G, the three conductor patterns 11 to 13 are laminated. After this, the three third insulating films 20c are laminated on the three conductor patterns 11 to 13. Next, the first ground pattern 31 is formed on one surface side of the insulating layer 20 formed by the first to third insulating films 20a to 20c by electroless plating or the like. Accordingly, the first ground pattern 31 is formed across the inside and the outside of the groove G.

In addition, in the first manufacturing method, in a case where the depth of the groove G is set to be approximately the same as the arrangement depth of the conductor patterns 11 to 13, the configuration of laminating the three second insulating films 20b is omitted.

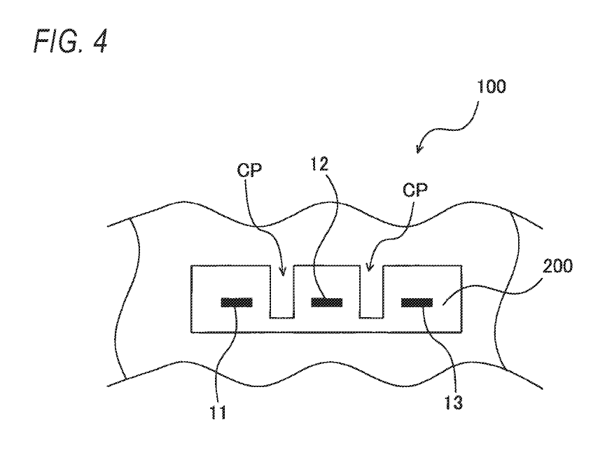

FIG. 4 is a sectional view illustrating a second manufacturing method of the transmission line 1 illustrated in FIGS. 1 and 2. The second manufacturing method is a method of extrusion molding of an insulating resin. First, using a metal mold 100 as illustrated in FIG. 4, the insulating resin 200 is extrusion-molded to three conductor patterns 11 to 13 arranged in parallel in a planar shape which are transmission paths of signals. Accordingly, the insulating layer 20 which surrounds the plurality of conductor patterns 11 to 13 in a substantially planar shape is formed (first process).

Next, the first ground pattern 31 is formed on one surface side of the insulating layer 20 formed in the first process, and the second ground pattern 32 is formed on the other surface side of the insulating layer 20, by electroless plating or the like (second process).

Here, in the mold 100 used in the first process, at each of the positions between the three conductor patterns 11 to 13 in a plan view, a projected portion CP for continuously forming the groove G in the longitudinal direction of the three conductor patterns 11 to 13 without dividing the insulating layer 20 is provided. Therefore, by the extrusion molding in the first process, the groove G is formed at each of the positions between the three conductor patterns 11 to 13.

In addition, in the second process, the first ground pattern 31 is continuously formed across the inside and the outside of the groove G by electroless plating or the like.

Next, the impedance characteristics and the crosstalk reduction characteristics of the transmission line 1 according to the embodiment will be described, but prior to this, the impedance characteristics and the crosstalk reduction characteristics of a transmission line which does not have the first ground pattern 31 in the groove G (transmission line according to a comparative example) will be described.

First, in the transmission line according to the comparative example, three patterns, such as a case where there is no groove (that is, a case where one surface side of the insulating layer is flush), a case where the conductor patterns 11 to 13 positioned at the intermediate depth of the insulating layer 20 and the depth of the groove G are approximately the same as each other (a case of x=0 in FIG. 2), and a case where the depth of the groove G is further 0.7 mm deeper than the case where the depth of the groove G is approximately the same as the depth of the conductor patterns 11 to 13 (a case of x=0.7 in FIG. 2), are employed. In addition, specific measurements were performed with respect to the three patterns.

In addition, in the transmission line according to the comparative example, the thickness of the insulating layer 20 (the thickness of the position other than the groove G in a case where the groove G is formed) was set to 1.46 mm, the thickness of the conductor patterns 11 to 13 was set to 0.03 mm, and the width was set to 1.15 mm. In addition, in a case of forming the groove G, the width w2 was set to 2 mm, and the distance w1 from the conductor patterns 11 to 13 to the groove G was set to 0.5 mm.

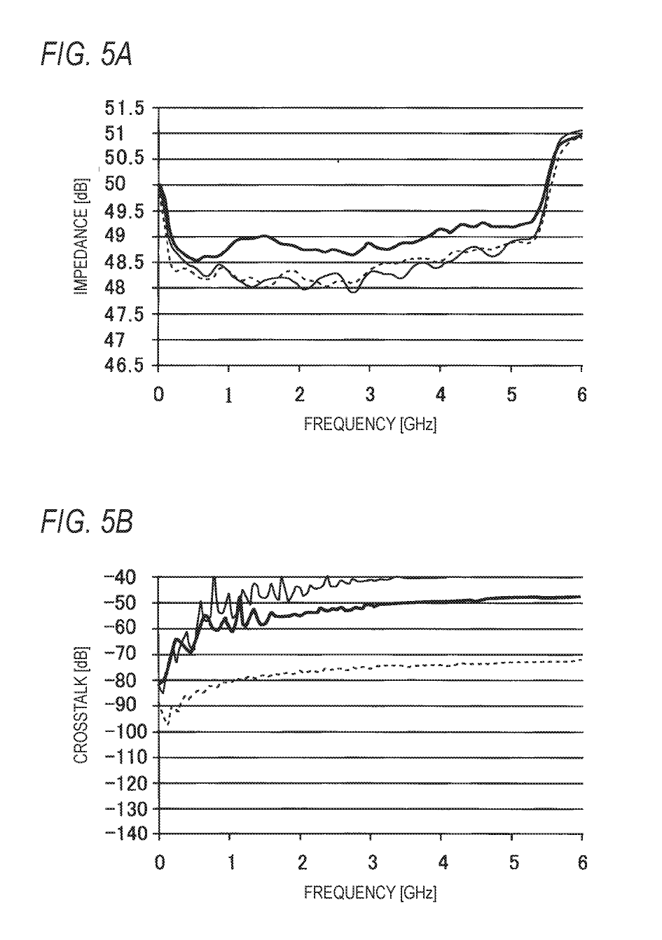

FIGS. 5A and 5B are graphs illustrating characteristics of the transmission line according to the comparative example, wherein FIG. 5A illustrates impedance characteristics, and FIG. 5B illustrates crosstalk reduction characteristics. In addition, in the graph illustrated in FIGS. 5A and 5B, the broken line indicates the characteristics in a case where there is no groove G, the solid line indicates the characteristics in a case where the depth of the groove G is x=0, the thick line indicates the characteristics in a case where the depth of the groove G is x=0.7 mm.

As illustrated in FIG. 5A, the impedance was approximately the same in a case where there is no groove G (refer to the broken line) and in a case where the depth of the groove G is x=0 (refer to the solid line). However, in a case where the depth of the groove G is x=0.7 mm, the impedance is caused to increase (refer to the thick line).

In addition, as illustrated in FIG. 5B, the crosstalk reduction characteristics are the most excellent in a case where there is no groove G (refer to the broken line), and in a case where there is the groove G, the crosstalk reduction characteristics tends to deteriorate (refer to the solid and the thick lines).

Above, from FIGS. 5A and 5B, it can be ascertained that a case where the first ground pattern 31 is not formed in the groove G, that is, a case where only a single hole is provided, is disadvantageous in terms of crosstalk, and more disadvantageous in terms of the impedance when the groove G becomes deeper. In this manner, in a case where the first ground pattern 31 is not formed on one surface side of the insulating layer 20, it can be ascertained that the groove G does not exist.

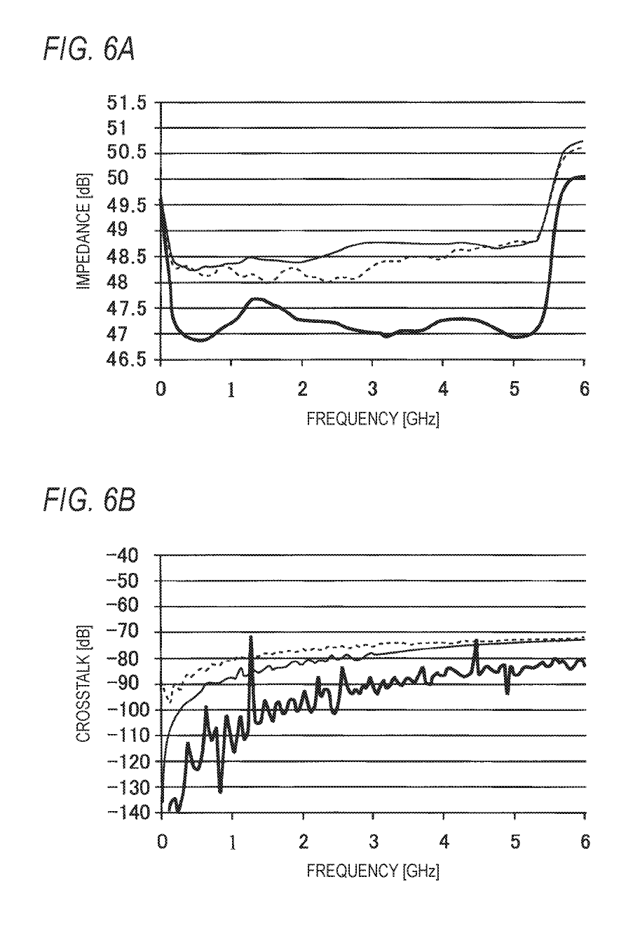

FIGS. 6A and 6B are graphs illustrating characteristics of the transmission line 1 according to the embodiment, wherein FIG. 6A illustrates impedance characteristics, and FIG. 6B illustrates crosstalk reduction characteristics. In addition, in the graph illustrated in FIGS. 6A and 6B, the broken line indicates the characteristics in a case where there is no groove G according to the comparative example, and the solid line and the thick line indicate the characteristics of the transmission line 1 according to this embodiment. The solid line indicates the characteristics in a case where the depth of the groove G is x=0, the thick line indicates the characteristics in a case where the depth of the groove G is x=0.7 mm. In addition, the other dimensions of the transmission line 1 according to the embodiment are the same as those of the comparative example.

As illustrated in FIG. 6A, the impedance was approximately the same in a case where there is no groove G (refer to the broken line) and in a case where the depth of the groove G is x=0 (refer to the solid line). However, it can be ascertained that, in a case where the depth of the groove G is x=0.7 mm, the impedance deteriorates (refer to the thick line).

Furthermore, as illustrated in FIG. 6B, it can be ascertained that the crosstalk reduction effect is higher in a case where there is the groove G than that in a case where there is no groove G (refer to the solid line and the thick line), and the crosstalk reduction effect is higher in a case where the groove G is deeper (refer to the thick line). Meanwhile, it can also be ascertained that, in a case where the depth of the groove G is x=0, it is possible to stabilize the crosstalk reduction effect (refer to the solid line).

Above, from FIGS. 6A and 6B, it can be ascertained that, in a case where the groove is formed between the conductor patterns 11 to 13 and the first ground pattern 31 is formed in the groove G, there is a certain crosstalk reduction effect.

In this manner, according to the transmission line 1 of the embodiment, since the insulating layer 20 has grooves G at each of the positions between the plurality of conductor patterns 11 to 13, and the first ground pattern 31 is continuously formed across the inside and outside of the groove G, the ground pattern 31 is positioned so as to enter between the plurality of conductor patterns 11 to 13, and accordingly, this functions as a shield foil and crosstalk is reduced. Therefore, it is not necessary to sufficiently ensure the distance between the conductor patterns 11 to 13 and it is possible to prevent the increase in size. In addition, since the conductor patterns 11 to 13 are arranged in parallel in a shape of a plane, it is also not necessary to form the conductor patterns 11 to 13 by offsetting the patterns. Therefore, the complication of the structure can be prevented. Therefore, it is possible to provide the transmission line 1 which is capable of preventing complication and an increase in size of the structure when reducing crosstalk.

In addition, since the groove is formed to have a depth which is equal to or greater than the arrangement depth of the plurality of conductor patterns, the ground pattern enters between the plurality of conductor patterns, and accordingly, the effect as a shield foil is further enhanced. Therefore, crosstalk can be further reduced.

In addition, in the manufacturing method (second manufacturing method) of the transmission line 1 according to the embodiment, the insulating resin is extrusion-molded by a mold having a projected portion for forming grooves G to form an insulating layer 20 having the grooves G continuously in the longitudinal direction, in a process similar to that of the insulation layer that does not have the groove G, it is possible to form the insulating layer 20 having the grooves G and to mitigate complication of the manufacturing process. Therefore, as the manufacturing method of the transmission line 1 which can prevent complication and an increase in size of the structure when reducing crosstalk, it is possible to provide a manufacturing method in which the complication of the manufacturing process is prevented.

Next, a second embodiment of the invention will be described. The transmission line according to the second embodiment is similar to that of the first embodiment, but a part of the configuration is different. Hereinafter, only the differences from the first embodiment will be described.

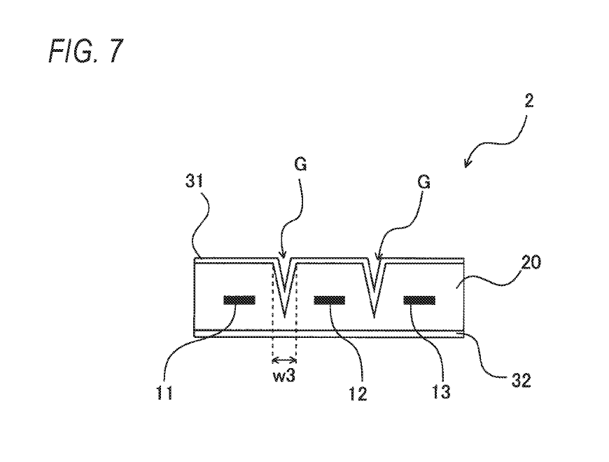

FIG. 7 is a sectional view illustrating a transmission line 2 according to the second embodiment. As illustrated in FIG. 7, in the transmission line 1 according to the first embodiment, the groove G has a recessed shape in a sectional view, but in the transmission line 2 according to the second embodiment, the groove G has a V shape in a sectional view.

Next, characteristics of the transmission line 2 according to the second embodiment and the transmission line 1 according to the first embodiment will be described by comparing the characteristics to each other. In addition, hereinafter, in a case where there is no groove G, three examples of a case where the widths w2 and w3 of the groove G (a reference numeral w3 is illustrated in FIG. 7) are small and a case where the widths w2 and w3 of the groove G are large, will be described.

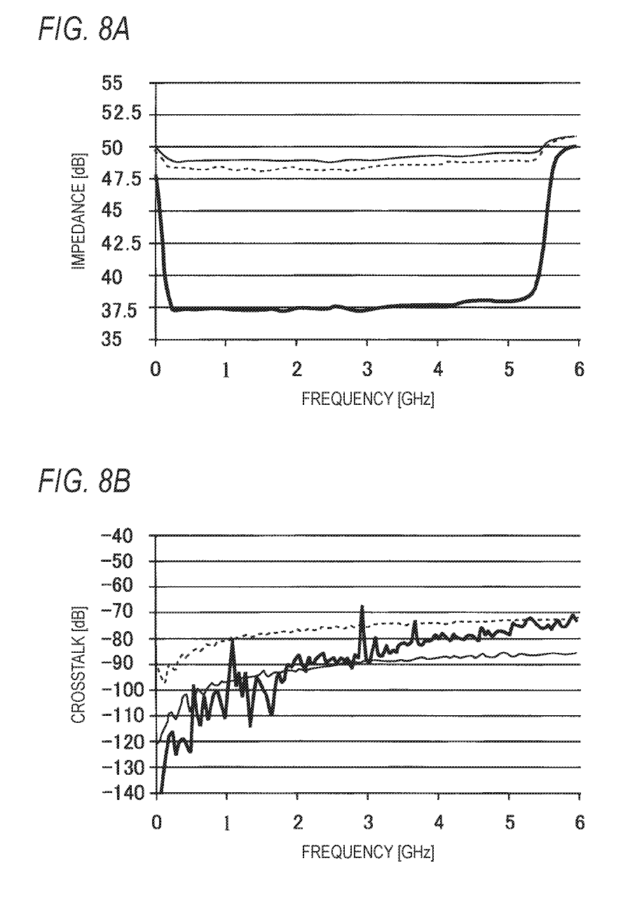

FIGS. 8A and 8B are graphs illustrating characteristics when the width w2 of the groove G in the transmission line 1 according to the first embodiment, wherein FIG. 8A illustrates impedance characteristics, and FIG. 8B illustrates crosstalk reduction characteristics. In addition, in FIGS. 8A and 8B, the broken line indicates the characteristics in a case where there is no groove G according to the comparative example, the solid line indicates the characteristics in a case where the width w2 of the groove G is 0.1 mm, the thick line indicates the characteristics in a case where the width w2 of the groove G is x=2.8 mm. In addition, the depth of the groove G is 1.25 mm (the thickness of the connecting portion 21 is 0.21 mm), and the other dimensions are the same as those of the comparative example described above.

As illustrated in FIG. 8A, the impedance was approximately the same in a case where there is no groove G (refer to the broken line) and in a case where the width w2 of the groove G is 0.1 mm (refer to the solid line). However, it can be ascertained that, in a case where the width w2 of the groove G is 2.8 mm, the impedance deteriorates (refer to the thick line). In other words, it can be ascertained that, when the width of the groove G increases, the impedance reduction effect is enhanced.

Furthermore, as illustrated in FIG. 8B, it can be ascertained that the crosstalk reduction effect is higher in a case where there is the groove G than that in a case where there is no groove G (refer to the solid line and the thick line). However, it can be ascertained that, according to the size of the width w2 of the groove G, there was no difference in the crosstalk reduction effect (refer to the solid line and the thick line). In particular, in a case where the width w2 of the groove G was 2.8 mm, the crosstalk reduction effect was not stabilized (refer to the thick line).

Above, from FIGS. 8A and 8B, it can be ascertained that the impedance becomes lower when the width w2 of the groove G is greater. However, when the width w2 of the groove G is large, the crosstalk reduction effect becomes unstable.

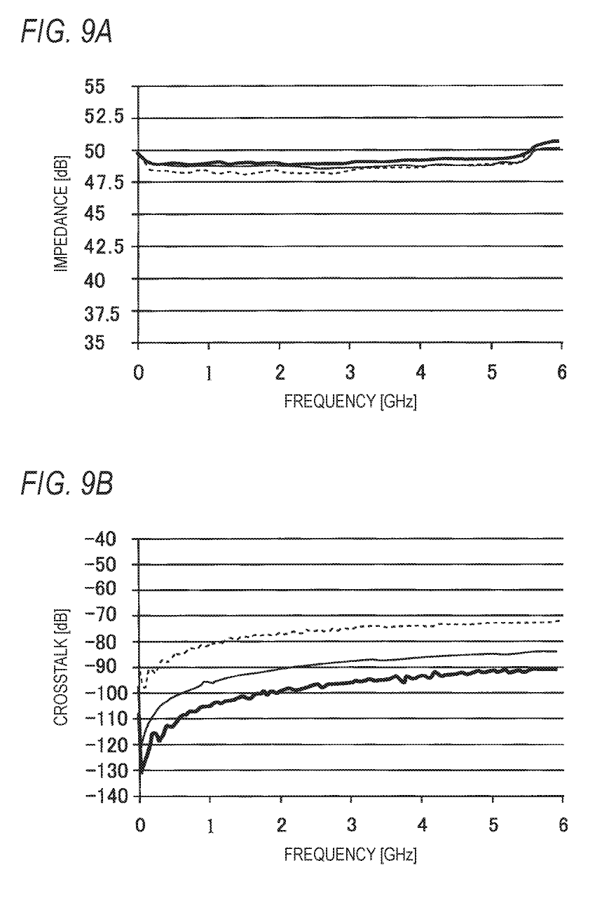

FIGS. 9A and 9B are graphs illustrating characteristics when the width w3 of the groove G changes in the transmission line 2 according to the second embodiment, wherein FIG. 9A illustrates impedance characteristics, and FIG. 9B illustrates crosstalk reduction characteristics. In addition, in FIGS. 9A and 9B, the broken line indicates the characteristics in a case where there is no groove G according to the comparative example, the solid line indicates the characteristics in a case where the width w3 (the width which is the maximum as illustrated in FIG. 7) of the groove G is 0.16 mm, the thick line indicates the characteristics in a case where the width w3 of the groove G is 1.75 mm. In addition, the depth of the groove G is 1.235 mm (the thickness of the connecting portion 21 is 0.225 mm), and additionally, the other dimensions are the same as those of the comparative example.

As illustrated in FIG. 9A, the impedance was approximately the same in a case where there is no groove G (refer to the broken line), in a case where the width w3 of the groove G is 0.16 mm (refer to the solid line), and in a case where the width w3 of the groove G is 1.75 mm (refer to the thick line).

As illustrated in FIG. 9B, it can be ascertained that the crosstalk reduction effect is high in an order of a case where there is no groove G (refer to the broken line), a case where the width w3 of the groove G is 0.16 mm (refer to the solid line), and the width w3 of the groove G is 1.75 mm (refer to the thick line). In particular, it can be ascertained that, even in a case where the width w3 of the groove G increases and becomes 1.75 mm, the crosstalk reduction effect was stabilized (refer to the thick line).

Above, from FIGS. 9A and 9B, it can be ascertained that the impedance does not depend on the presence or absence of the groove G or the width w3 of the groove G. Furthermore, it can be ascertained that, when the groove G is V-shaped, the crosstalk reduction effect is enhanced as the width w3 of the groove G increases, and even when the width w3 of the groove G is large, the crosstalk reduction effect is stabilized.

In this manner, according to the transmission line 2 of the second embodiment, similar to the first embodiment, it is possible to provide the transmission line 2 which is capable of preventing the complication and the increase in size of the structure when reducing crosstalk. In addition, since the groove G is formed to have a depth which is equal to or greater than the arrangement depth of the plurality of conductor patterns 11 to 13, the ground pattern 31 enters between the plurality of conductor patterns 11 to 13, and accordingly, the effect as a shield foil is further enhanced. Therefore, crosstalk can be further reduced.

In addition, according to the manufacturing method (second manufacturing method) of the transmission line 2 of the second embodiment, similar to the first embodiment, it is possible to provide a manufacturing method that prevents the complication of the manufacturing process.

Furthermore, according to the second embodiment, since the groove G is formed to have a V shape in a sectional view, the crosstalk reduction effect can be stabilized.

Above, although the invention is described based on the embodiments, the invention is not limited to the above-described embodiments, and modifications may be made without departing from the spirit of the invention, or an appropriately known or well-known technologies may be combined within a possible range.

For example, in the above-described embodiments, three conductor patterns 11 to 13 are exemplified, but the invention is not limited thereto, and two or four or more conductor patterns may be used. Furthermore, in the above-described embodiment, the plurality of conductor patterns 11 to 13 have substantially the same width and substantially the same thickness, but the invention is not limited thereto, and at least one of the widths or the thicknesses may be different.

Furthermore, in the above-described embodiment, a case where the widths w2 and w3 or the depth of each groove G are the same is described as an example, but the invention is not limited thereto, and the widths w2 and w3 or the depth of a part of the grooves G may be different.

What is claimed is:

1. A transmission line comprising:
a plurality of conductor patterns as transmission paths of signals arranged in parallel in a planar shape;
an insulating layer surrounding the plurality of conductor patterns in a substantially planar shape;
a first ground pattern formed on one surface side of the insulating layer; and
a second ground pattern formed on the other surface side of the insulating layer,
wherein the insulating layer includes one or more grooves formed continuously in a longitudinal direction of the plurality of conductor patterns on the one surface side without dividing the insulating layer at each of one or more positions between the plurality of conductor patterns in a plan view, and
wherein the first ground pattern is continuously formed over the one surface side.

2. The transmission line according to claim 1,
wherein each of the one or more grooves has a depth which is equal to or greater than a depth of the plurality of conductor patterns from a top surface of the one surface side.

3. The transmission line according to claim 1,
wherein each of the one or more grooves has a V shape in a sectional view.

4. A manufacturing method of a transmission line, comprising:
extrusion-molding an insulating resin into a plurality of conductor patterns as transmission paths of signals arranged in parallel in a planar shape, so as to form an insulating layer surrounding the plurality of conductor patterns in a substantially planar shape;
forming a first ground pattern on one surface side of the insulating layer formed in the extrusion-molding; and
forming a second ground pattern on the other surface side of the insulating layer formed in the extrusion-molding,
wherein, in the extrusion-molding, the insulating resin is extrusion-molded with a mold having a projected portion, so as to continuously form one or more grooves in a longitudinal direction of the plurality of conductor patterns without dividing the insulating layer at each of one or more positions between the conductor patterns in a plan view, and
wherein in the forming the first ground pattern, the first ground pattern is continuously formed over the one surface side.
